(19) United States
(12) Patent Application Publication
(10) Pub. No.: US 2006/0114008 A1
(43) Pub. Date: Jun. 1, 2006

(54) Probe card for testing semiconductor element, and semiconductor device tested by the same

(76) Inventor: Daisuke Fujii, Tokyo (JP)

Correspondence Address: RABIN & BERDO, P.C., 1101 14th Street, Suite 500, Washington, DC, 20005, US

(21) Appl. No.: 11/212,762

(22) Filed: Aug. 29, 2005

(30) Foreign Application Priority Data
Nov. 29, 2004 (JP) 2004-343675

(51) Int. Cl. G01R 31/02

(52) U.S. Cl. 324/754

(57) ABSTRACT

An apparatus which reduces a contact resistance by appropriately overdriving a measuring probe of a probe card to ensure a stable contact pressure. The probe card comprises a measuring probe configured to contact a terminal of a semiconductor element formed in a semiconductor wafer, and a base plate to which the measuring probe is attached, wherein a dummy probe is provided in an area outside the probe installation area for the measuring probe on the base plate. The end face of the dummy probe is set as a reference plane to provide a reference when the distance between the terminal on the semiconductor wafer and the tip of the measuring probe is set.

### BACKGROUND OF THE INVENTION

1. Field of the Invention

The present invention relates to a probe card which is made to contact a terminal of a semiconductor element formed in a semiconductor wafer so as to perform an electrical test on the semiconductor element. The invention further includes a semiconductor device tested by the probe card.

2. Description of the Related Art

With the recent increase in the density of semiconductor elements, a probe card with more probes and a finer probe pitch is required. To meet this demand, the conventional probe card forms measuring probes on the base plate of a probe card by plating so as to align the contact points of the tips of the measuring probes, and sets an adequate amount of overdriving to ensure a substantially uniform contact pressure, which is described in, for example, Japanese Patent Publication No. 7-82027 (see paragraphs 0003 to 0007 on page 2 and FIG. 1).

A method of detecting the position of the tip of such a measuring probe is to use the outline of an image obtained by photographing the tip of the measuring probe that is installed at a tilt angle and attached to a base plate. Then, on the basis of the detected probe position, the tip of the measuring probe is aligned with a terminal of a semiconductor element and in contact with each other to perform an electrical test on the semiconductor element, as described in, for example, Japanese Patent Kokai No. 2000-249745 (see paragraph 0017 on page 3 to paragraph 0023 on page 4 and FIG. 1).

As described above, the technology described in Japanese Patent Kokai No. 2000-249745 detects the position of the tip of a measuring probe from the outline of an image obtained by photographing the tip of the measuring probe to perform alignment in the horizontal direction. This method however has a problem in that when displacement in the vertical direction occurs due to, for example, wear and aging of the stage on which an elevator mechanism for a probe card and a semiconductor wafer are installed, a measuring probe contacts a terminal with an improper amount of overdriving, causing the contact pressure to be too small and therefore a contact resistance to be increased. As a result, it is difficult to perform electrical testing correctly.

This results in an increase in the defective rate of the semiconductor device to be produced.

### SUMMARY OF THE INVENTION

An object of the present invention is to provide means for reducing a contact resistance by appropriately overdriving a measuring probe to ensure a stable contact pressure.

According to one aspect of the present invention, there is provided a probe card comprising a measuring probe configured to contact a terminal of a semiconductor element formed in a semiconductor wafer and a base plate to which the measuring probe is attached, wherein a dummy probe is provided in an area outside the measuring probe on the base plate and an end face of the dummy probe is set as a reference plane to provide a reference when the distance between the terminal of the semiconductor wafer and the tip of the measuring probe is set.

It is thereby facilitated to measure the height of the probe card. Therefore, even if displacement in the vertical direction occurs in a test apparatus, the measuring probe can press the terminal with an adequate amount of overdriving, so that the contact resistance can be reduced. As a result, an electrical test of a semiconductor wafer can be performed correctly and thus a defective rate of semiconductor devices as products can be advantageously reduced.

According to another aspect of the present invention, there is provided a method of testing a semiconductor element using a probe card having a measuring probe configured to contact a terminal of a semiconductor element formed in a semiconductor wafer placed on a stage, a base plate to which the measuring probe is attached, and a dummy probe provided outside the measuring probe on the base plate to form a reference plane to provide a reference when a distance between the semiconductor wafer and the measuring probe is set. The method comprises the steps of measuring a height of the reference plane of the dummy probe, adjusting a height of a probe card by moving the probe card vertically on the basis of the measured height so as to match the height of the probe card with a preset value of the distance between the terminal of the semiconductor element and the tip of the measuring probe, placing the semiconductor wafer to be tested at a predetermined position on the stage, and pressing the tip of the measuring probe to the terminal of the semiconductor element on the semiconductor wafer.

### BRIEF DESCRIPTION OF THE DRAWINGS

FIG. 1 is a side view showing a probe card of an embodiment according to the present invention;

FIG. 2 is a view seen from the direction of an arrow A shown in FIG. 1;

FIG. 3 is a schematic diagram illustrating a test apparatus for a semiconductor wafer of the embodiment according to the present invention;

FIG. 4 is a schematic diagram illustrating an installation place of a dummy probe in relation to a semiconductor wafer of the embodiment according to the present invention;

FIG. 5 is schematic diagrams illustrating the test steps for a semiconductor wafer of the embodiment according to the present invention; and

FIG. 6 is a schematic diagram illustrating an amount of overdriving the tip of a needle-shaped member of the embodiment according to the present invention.

### DETAILED DESCRIPTION OF THE INVENTION

An embodiment of a probe card according to the present invention will be hereinafter described with reference to the accompanying drawings.

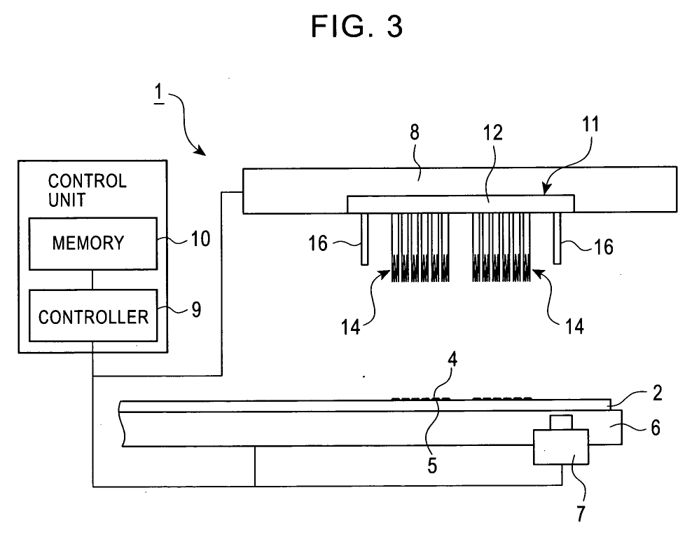

In FIG. 3, the reference numeral 1 denotes a test apparatus.

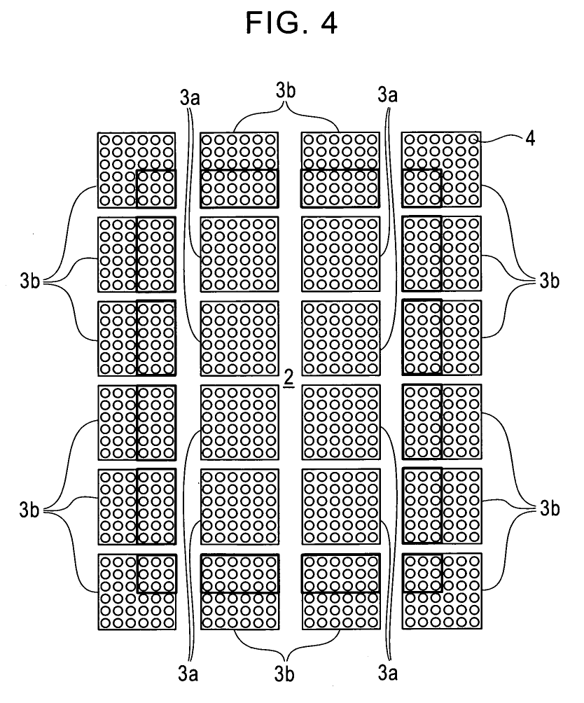

The reference numeral 2 denotes a semiconductor wafer in which a plurality of semiconductor elements 3a and 3b (see FIG. 4, wherein they are referred to together as semiconductor elements 3 when it is not necessary to distinguish their positions) such as large scale integrated circuits (LSIs) are formed. In the embodiment, the semiconductor wafer 2 on which the semiconductor elements 3 are formed is divided into chips to fabricate the semiconductor devices as wafer level chip size packages.

The reference numeral 4 denotes solder balls used as terminals, which are formed as hemispherical bumps by attaching solder on the external connecting terminals 5 of the semiconductor element 3.

The reference numeral 6 denotes a stage of the test apparatus, which is provided with an X-Y coordinate adjustable mechanism (not shown) and on which the semiconductor wafer 2 is placed.

The reference numeral 7 denotes a camera having a zoom function and serving as distance measuring equipment, which is installed in the vicinity of the origin location in the stage 6 where the semiconductor wafer 2 is placed when testing is started. The camera 7 also has a function to recognize an object from a photographed image of the object, and a distance measuring function for detecting a focal length by using, for example, the reflection of sound waves to measure the distance up to the recognized object.

The visual field of the camera 7 is made to photograph the whole of a single semiconductor element 3 with the minimum magnification, and to photograph only the entire reference plane 18 of a dummy probe 16 (described later) and the vicinity of the dummy probe 16 with the maximum magnification.

The reference numeral 8 denotes a probe card attachment plate carrying thereon relays, resistors, power supply routes, etc., and wirings for connecting such elements, which are necessary for electrically testing the semiconductor elements 3 on the semiconductor wafer 2. The probe card 11 is also attached to the probe card attachment plate 8.

The probe card attachment plate 8 is further provided with an elevator mechanism (not shown) and a rotation mechanism (not shown) rotating around a horizontal axis so that the position of the probe card 11 in the up and down (vertical) direction and the slope thereof are adjustable.

The reference numeral 9 denotes a controller in the controller unit of the test apparatus 1. The controller 9 controls movements such as the travel of the stage 6 in the X-Y direction, and the vertical movement and rotating movement of the probe card attachment plate 8.

The reference numeral 10 denotes a memory that stores, for example, movement control programs executed by the controller 9 and results processed by the programs.

The memory 10 also stores a setting reference distance, a distance reference value, and the like which are set up in advance. The setting reference distance is set up such that the height of the reference plane 18 of a dummy probe 16 corresponds to a focal length detected by the camera 7. The distance reference value is an appropriate distance between the solder balls 4 formed on the semiconductor wafer 2 and the tips of measuring probes 13 (tips of needle-shaped members 15 in the embodiment). The appropriate distance is obtained by adding an adequate amount of overdriving δ to the distance between the solder balls 4 on a semiconductor element 3 formed in the semiconductor wafer 2 placed on the stage 6 and the tips of the measuring probes 13 of the probe card 11 located at the setting reference distance, where the amount of overdriving δ is defined as a driving distance after the tips of the measuring probes 13 contact the terminals such as the solder balls 4.

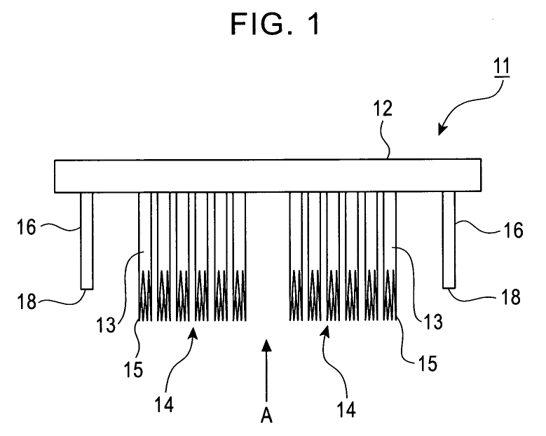

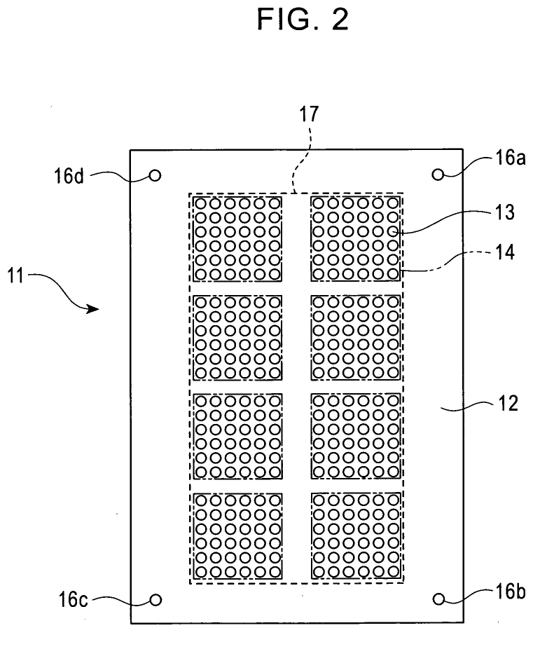

In FIG. 1 and FIG. 2, the reference numeral 12 denotes the base plate of the probe card 11, which is formed in a substantially rectangular shape and aligned with and secured to the probe card attachment plate 8.

The reference numeral 13 denotes measuring probes that are cylindrical members formed of conductive material such as metal. Each of the measuring probes has a smaller diameter than a diameter of the solder ball 4, to which contact is made. The measuring probes 13 are divided into probe groups 14 (i.e., a plurality of measuring probes 13 enclosed by a chain double-dashed line in FIG. 2), each of which corresponds to a plurality of the solder balls 4 on a single semiconductor element 3 to be tested. The measuring probes 13 are secured to the base plate 12 so as to be connected to the predetermined wirings when the base plate 12 is attached to the probe card attachment plate 8. In the present embodiment, eight semiconductor elements 3 are tested simultaneously. The measuring probes 13 are thus divided into eight probe groups 14 and secured to the base plate 12.

The reference numeral 15 denotes needle-shaped members (projections), which are formed to be disposed on the opposite side end of the measuring probe 13 from the base plate 12. Specifically, the needle members are formed in a crown shape at the tip of the measuring probe 13.

The reference numeral 16 denotes dummy probes (suffixes a to d are added only when it is necessary to distinguish their locations from each other as shown in FIG. 2). Each of the dummy probes is a cylindrical member, formed of metal material or the like, having a diameter substantially identical to that of the measuring probe 13. The dummy probes 16 are installed outside a probe installation area 17 (area enclosed by a dashed line in FIG. 2). The probe installation area 17 is disposed in a substantially central area of the base plate 12, and the probe groups 14 are installed therein. The end face of the opposite side end of the dummy probe 16, from the base plate 12, is formed flat so that it can function as a reference plane 18 for setting the distance reference value at the start of testing.

The length of the dummy probes 16 is set to be shorter than that of the measuring probes 13. Specifically, the length is set such that the dummy probes 16 do not contact the semiconductor wafer 2 when the measuring probes 13 contact the solder balls 4 formed on the semiconductor wafer 2 during testing.

In this embodiment, the measuring probes 13 are set to a length of about 0.75 mm, and the dummy probes 16 are set to a length of about 0.3 mm. Further, the dummy probes 16 are installed outside the four corners of the probe installation area 17, one for each corner, so that four dummy probes 16 are installed in total.

The number of the dummy probes 16 may be one or a plurality. When a plurality of dummy probes 16 are installed, it suffices to install at least three dummy probes or three measuring points outside at least two sides of the substantially rectangular probe installation area 17 so as to be able to define a plane by the three points. Further, as shown in FIG. 4, it is preferable for the dummy probes 16 to be installed at the locations corresponding to the solder balls 4 belonging to about half of the areas of the semiconductor elements 3b (area enclosed by a thick solid line in FIG. 4) enclosing the outside of the semiconductor elements 3a to be tested.

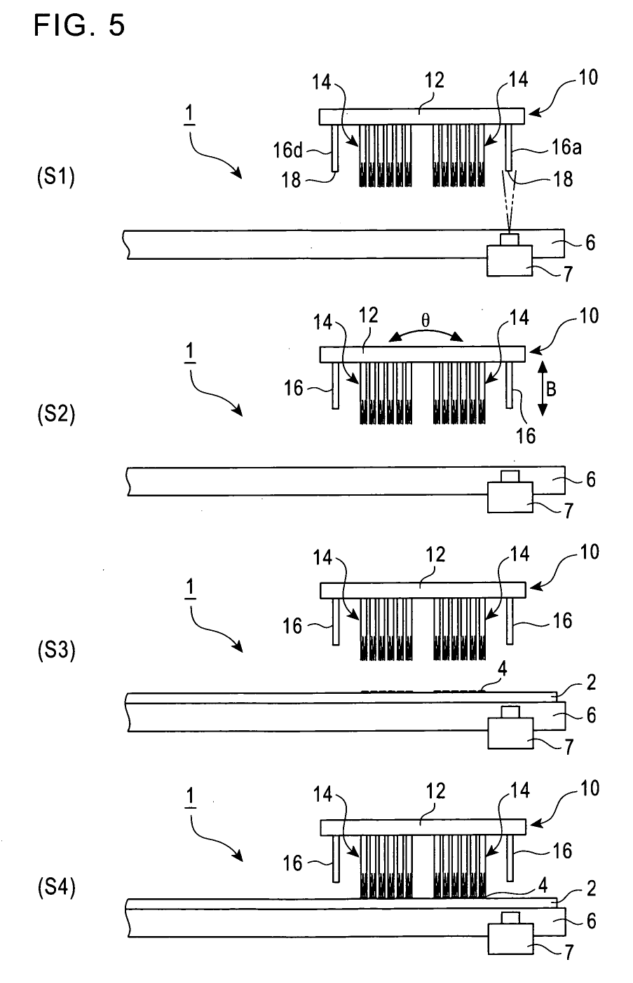

The method of testing a semiconductor wafer according to the embodiment will be hereinafter described in accordance with steps S1 to S4 in FIG. 5.

In step S1 (measuring step of the reference plane height), before starting a test of the semiconductor wafer 2, the controller 9 in the control unit of the test apparatus 1 moves the stage 6 so as to position the probe card 10 to a base location where a test of the semiconductor wafer 2 is started. Subsequently, the magnification of the camera 7 installed on the stage 6 is minimized, and then the stage 6 is moved in the X-Y direction to search the dummy probe 16a shown in FIG. 2. When the dummy probe 16a is recognized by an image recognition, the reference plane 18 of the dummy probe 16a is focused on with the maximum magnification to detect the focal length.

Next, in the similar way as described above, the dummy probe 16b is recognized by moving the camera 7 and the focal length of the reference plane 18 of the dummy probe 16b is detected. Likewise, the focal lengths of the reference planes 18 of the dummy probes 16c and 16d are also detected, so that the heights of the reference planes 18 of the dummy probes 16a to 16d are measured.

In step S2 (adjusting step of the probe card height), the controller 9 obtains an offset of the probe card position on the basis of the measured height of each reference plane 18.

Specifically, by averaging the measured heights of the reference planes 18, a current distance to the reference planes 18 is obtained, and the difference between the averaged length and the setting reference distance read from the memory 10 is calculated to obtain an offset in the up and down direction shown by an arrow B in FIG. 5.

Further, the height of the reference plane 18 of the dummy probe 16 that is located at the lowest position is extracted from among the measured heights of the reference planes 18, and the slope angles and slope directions of the reference plane, with respect to the other dummy probes 16, are calculated from: the differences between the extracted height and the heights of the reference planes 18 of the other dummy probes 16; and the distances from the dummy probe at teh lowest position to the other dummy probes 16. An offset of the slope angle and the slope direction of a plane of the probe card are thereby obtained in order to arrange a plane including the tips of the measuring probes 13 in parallel with the top surface of the semiconductor wafer 2 (in this embodiment, the plane including the tips of the measuring probes 13 is arranged horizontally).

Next, on the basis of the obtained offset in the vertical direction, and slope direction and offset of the slope angle of the plane of the probe card, the elevator mechanism (not shown) installed on the probe card attachment plate 8 is operated to vertically move the probe card 11 for adjustment to the setting reference distance set up in advance, and the rotation mechanism (not shown) is operated to rotate the probe card 11 in the direction shown by an arrow θ in FIG. 5 for adjustment of the slope of the plane of the probe card in parallel with the top surface of the semiconductor wafer 2.

In step S3 (placing step of the semiconductor wafer), the semiconductor wafer 2 to be tested is transported to the stage 6 and set at a predetermined position by using, for example, a vacuum suction.

In this embodiment, the semiconductor wafer 2 is set at a position where each solder ball 4 of the first eight semiconductor elements 13 to be tested matches each position of the corresponding measuring probe 13, that is, the semiconductor wafer 2 is set at the base location where the test is started.

In step S4 (pressing step of the measuring probe), after the semiconductor wafer 2 to be tested has been set at the predetermined position, the controller 9 reads the distance reference value of the probe card 11 from the memory 10 to use the distance as a distance for lowering the probe card 11. Then, the probe card 11 is lowered by the elevator mechanism (not shown) installed on the probe card attachment plate 8. Accordingly, the tips of the needle-shaped members 15 of the measuring probes 13 press the solder balls 4 on the semiconductor elements 3 on the semiconductor wafer 2 to electrically test the semiconductor elements 3.

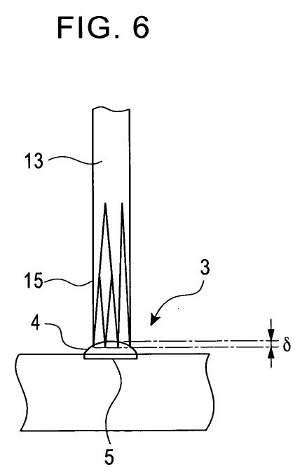

In this case, since the distance reference value includes the amount of overdriving δ shown in FIG. 6, when the tips of the needle-shaped members contact and press the solder balls 4, the tips drive into the solder balls 4 with a depth corresponding to the amount of overdriving δ. Therefore, the contact resistances are reduced so that the electrical test can be performed correctly.

Subsequently, the controller 9 raises the probe card 11 up to the setting reference distance, and moves the stage 6 with the semiconductor wafer 2 so that each solder ball 4 of the eight semiconductor elements 3, to be tested next, matches each position of the corresponding measuring probe 13 of the probe card 11. Then, in a similar manner as in the above step S4, the tips of the measuring probes 13 press the solder balls 4 to electrically test the semiconductor elements 3. This operation is sequentially repeated to complete the electrical test of the semiconductor elements 3 formed in the semiconductor wafer 2.

The semiconductor elements 3 formed in the semiconductor wafer 2 are thus electrically tested according to the embodiment, after which the tested semiconductor wafer 2 is divided into chips each having a semiconductor element 3 to fabricate the semiconductor device in wafer level chip size packages.

Alternatively, the semiconductor wafer 2 may be divided into a strip shape or may not be divided at all to function as a semiconductor device, while leaving a plurality of the semiconductor elements 3 formed on the semiconductor wafer 2.

The operations in the above steps S1 and S2 may be performed each time a single semiconductor wafer 2 is set, or at a certain period of time (for example, on a manufacturing lot basis of the semiconductor wafers 2), or on demand basis.

When a single dummy probe 16 is used, the height of the reference plane 18 of this single dummy probe 16 is set to a current distance to the reference plane 18, and an offset in the vertical direction may be obtained from the difference between this current distance and the setting reference distance.

As described above, in the present embodiment, a reference plane, which is used to set the distance between the solder balls on a semiconductor wafer and the tips of the measuring probes, is formed on the end of a dummy probe installed in an area outside the measuring probes of a probe card, thereby facilitating the measurement of the height of the probe card. Therefore, even if displacement in the vertical direction occurs due to, for example, wear and aging of a stage on which an elevator mechanism for the probe card and a semiconductor wafer are installed, the measuring probes can press the solder balls with an adequate amount of overdriving. Needle-shaped members are thereby driven into the solder balls to an adequate depth so that the contact resistances can be reduced. As a result, an electrical test of a semiconductor wafer can be performed correctly and therefore the defective rate of the semiconductor element as the product can be reduced.

When a needle-shaped member is provided on the end of a measuring probe, it is difficult for a camera to focus on the tip of the needle-shaped member. Even in this case, using the reference plane of a dummy probe facilitates measuring the height of a probe card.

Further, if at least three dummy probes are disposed outside at least two sides of the substantially rectangular probe setting area in which measuring probes are installed, it is possible to easily obtain a slope of a plane of a probe card from the measured heights of the reference planes of the dummy probes. A plane including the tips of the measuring probes can thereby be made in parallel with the top surface of a semiconductor wafer so that the tips of the measuring probes can be uniformly driven into the solder balls on a semiconductor element corresponding to a single probe group or the solder balls on semiconductor elements corresponding to a plurality of probe groups. As a result, an electrical test of semiconductor elements can be performed stably, which is especially effective in the probe card with which a plurality of semiconductor elements are simultaneously tested.

Furthermore, in the test process of semiconductor elements formed in a semiconductor wafer, a test step is provided in which the height of a probe card is adjusted so as to become a predetermined distance reference value. This adjustment is done using the measured height of the reference plane of a dummy probe before the test of the semiconductor wafer is performed. Accordingly, the electrical test of the semiconductor elements can be always performed with an adequate amount of overdriving and with precision.

The present invention can also be applied to the case in which a terminal to be contacted by the tip of a measuring probe is a flat pad such as an electrode pad or an external connecting terminal. In this case, since it is facilitated to set an adequate amount of overdriving in a similar manner as the above case, the tip of the measuring probe can press the terminal with an adequate contact pressure corresponding to an amount of overdriving δ, wherein the adequate contact pressure is produced by: elastic force of a measuring probe (for example, elastic force produced by bending of a measuring probe installed at an angle, as described above in Japanese Patent Kokai No. 2000-249745); or elastic force of a spring element provided in a measuring probe or a probe card attachment plate. As a result, the contact resistances are reduced so that an electrical test can be performed correctly.

The above embodiment has been described based on a camera with a zoom function as distance measuring equipment in order to acknowledge the position of a dummy probe, to detect the focal length up to the reference plate of the dummy probe by the reflection of sound waves, and to measure the height of a probe card. However, any other cameras or a microscope with a distance measuring function may also be used in which a focal length is detected by the sharpness of an image of an object photographed by a charge coupled device (CCD) or the like to measure the distance to the object. Alternatively, combination of distance measuring equipment by using ultrasonic waves, infrared light, electromagnetic waves, or the like and a camera or any other devices for acknowledging the position of a dummy probe may also be used.

The present invention is based on Japanese Patent Application No. 2004-343675 which is hereby incorporated by reference in its entirety.

What is claimed is:

1. A probe card comprising:
a measuring probe configured to contact a terminal of a semiconductor element formed in a semiconductor wafer; and
a base plate to which the measuring probe is attached,
wherein a dummy probe is provided in an area outside the measuring probe on the base plate, and
an end face of the dummy probe is set as a reference plane to provide a reference when a distance between the terminal of the semiconductor element and a tip of the measuring probe is set.

2. The probe card according to claim 1, wherein a substantially rectangular probe setting area to which the measuring probe is attached is provided on the base plate, and at least three dummy probes are disposed outside of at least two sides of the probe setting area.

3. The probe card according to claim 1, wherein a distance from the base plate to the end face of the dummy probe is shorter than a distance from the base plate to the tip of the measuring probe.

4. The probe card according to claim 1, wherein the tip of the measuring probe forms a needle-shaped member.

5. The probe card according to claim 4, wherein the needle-shaped member is disposed in a crown shape at the tip of the measuring probe.

6. The probe card according to claim 1, wherein the terminal of the semiconductor element is a solder ball.

7. The probe card according to claim 1, wherein a position of the dummy probe corresponds to a position of a terminal in substantially half of an area within a semiconductor element disposed outside of, and in the vicinity of a semiconductor element to be tested, said half of the area being located on a near side to the semiconductor element to be tested.

8. The probe card according to claim 6, wherein the measuring probe comprises a cylindrical member having a diameter smaller than a diameter of the solder ball.

9. The probe card according to claim 1, wherein the measuring probe comprises a probe group corresponding to a plurality of terminals of a single semiconductor element to be tested.

10. The probe card according to claim 9, wherein the probe card comprises a plurality of the probe groups.

11. A semiconductor device having said semiconductor element formed by dividing a semiconductor wafer into chips of the semiconductor elements, wherein the semiconductor wafer is tested using the probe card according to claim 1.

12. A test apparatus for testing a semiconductor element including a probe card having a measuring probe configured to contact a terminal of a semiconductor element formed in a semiconductor wafer placed on a stage, a base plate to which the measuring probe is attached, and a dummy probe provided outside the measuring probe on the base plate to form a reference plane to provide a reference when a distance between the semiconductor wafer and the measuring probe is set, the test apparatus comprising:
measuring means to measure a height of the reference plane of the dummy probe;
adjusting means to adjust a height of a probe card by moving the probe card vertically on the basis of the measured height so as to match the height of the probe card with a preset value of a distance between the terminal of the semiconductor element and a tip of the measuring probe;
placing means to place the semiconductor wafer to be tested at a predetermined position on the stage; and
press means to press the tip of the measuring probe to the terminal of the semiconductor element on the semiconductor wafer.

13. The test apparatus according to claim 12, wherein:
at least three dummy probes are disposed outside of at least two sides of a substantially rectangular probe setting area to which the measuring probe provided on the base plate is attached;
the heights of the reference planes of all of the measuring probes are measured by the measuring means; and
a slope obtained from the heights of the reference planes is adjusted by the adjusting means.
